(19) United States
(12) Patent Application Publication
(10) Pub. No.: US 2023/0096742 A1
(43) Pub. Date: Mar. 30, 2023

(54) Mounting method for an integrated semiconductor wafer device, and mounting device able to be used therefor

(71) Applicant: LPKF Laser & Electronics AG, Garbsen (DE)

(72) Inventors: Roman OSTHOLT, Langenhagen (DE); Norbert AMBROSIUS, Garbsen (DE); Rafael SANTOS, Hannover (DE)

(21) Appl. No.: 17/759,319

(22) PCT Filed: Jan. 12, 2021
(86) PCT No.: PCT/EP2021/050495

§ 371 Date: Jul. 22, 2022

(30) Foreign Application Priority Data
Jan. 23, 2020 (DE) 10 2020 200 817.5

(51) Int. Cl. H01L 21/52; H01L 21/67

(52) U.S. Cl. CPC H01L 21/52; H01L 21/67121

(57) ABSTRACT

A mounting method for an integrated semiconductor wafer device including a glass substrate a recess, at least one semiconductor wafer that is arranged in the recess, and at least one spring element engaging in the recess for maintaining the position or orienting the semiconductor wafer, wherein the method includes providing the glass substrate with a relaxed spring element engaging in the contour space of the semiconductor wafer, providing a spring manipulator substrate with a manipulation element adapted to the contour space and/or the at least one spring element, displacing the glass substrate in relation to the spring manipulator substrate such that its manipulation element runs into the recess, placing the semiconductor wafer into the recess, and displacing the glass substrate back in relation to the spring manipulator substrate such that its manipulation element moves out of the contour space of the semiconductor wafer, releasing the spring element.

### CROSS-REFERENCES TO RELATED APPLICATIONS

This application claims the priority of German Patent Application, Serial No. DE 10 2020 200 817.5, filed Jan. 23, 2020, the content of which is incorporated herein by reference in its entirety as if fully set forth herein.

### FIELD OF THE INVENTION

The invention relates to a mounting method for an integrated semiconductor wafer device, in particular an integrated semiconductor component arrangement, as manufacturing intermediate product, and to a mounting device for performing this mounting method.

### BACKGROUND OF THE INVENTION

The following information is intended to clarify the background of the invention. The semiconductor industry has experienced rapid growth thanks to continuous improvements in the integration density of various electronic components. For the most part, this improvement in the integration density results from repeated reductions in the minimum feature size, meaning that more components may be integrated into a particular region.

Since the demand for miniaturization, higher speed and greater bandwidth as well as lower power consumption has increased in recent times, a need has arisen for smaller and more creative packaging techniques for unpackaged semiconductor wafers, also referred to as dies.

In the course of continuing integration, an increasing number of assemblies that were previously installed next to one another as individual semiconductor wafers on a circuit board are being combined to form a “larger” semiconductor wafer. “Larger” in this case means the number of circuits on the die, since the absolute size is able to decrease through continuing refinement of the manufacturing process.

In a stacked semiconductor device, active circuits such as logic, memory, processor circuits and the like are manufactured at least partly on separate substrates and then bonded physically and electrically to one another in order to form a functional device. Such bonding processes apply highly sophisticated techniques, with improvements being desired.

A combination of two complementary assemblies, such as for example CPU and cache, on a semiconductor wafer may be rewritten using the term “on-die”: the CPU has the cache “on-die”, that is to say directly on the same semiconductor wafer, which considerably speeds up the exchange of data. Assembly and packaging technology deals with the further processing of the semiconductor wafer packaging and integration into the circuit environment.

Many integrated circuits are usually manufactured on a single semiconductor wafer and individual semiconductor wafers on the wafer are singulated by sawing the integrated circuits along a cutting line. The individual semiconductor wafers are usually encapsulated separately, for example in multi-semiconductor wafer modules or in other types of packaging.

A wafer level package (WLP) structure is used as a packaging structure for semiconductor components of electrical products. An increased number of electrical input/output (I/O) contacts and an increased demand for high-power integrated circuits (ICs) has led to the development of fanout WLP structures that allow larger centre distances for the electrical I/O contacts.

In this case, use is made of an electrical redistribution structure that comprises one or more electrical redistribution layers (RDL). Each RDL may be designed as a structured metallization layer and serves as an electrical interconnection that is designed to connect the electronic component, embedded in the encapsulation, to the external terminals of the semiconductor component package and/or one or more electrode(s) of the semiconductor wafer(s) arranged on the underside of the semiconductor component package.

DE 10 2007 022 959 A1 discloses a semiconductor package in which a semiconductor wafer is embedded in a casting compound. A redistribution layer is provided with solder balls for surface mounting of the semiconductor wafer package. Through glass vias through the semiconductor package are provided with solder material on a surface of the semiconductor package, by way of which a second semiconductor package is able to be stacked on the first one.

U.S. Pat. No. 6,716,670 B1 discloses a semiconductor wafer package for surface mounting. Contacts are provided on a main surface, to which contacts a second semiconductor wafer package is able to be attached.

DE 10 2006 033 175 A1 discloses an electronic module that comprises a logic part and a power part. The logic part and power part are arranged on substrates that are arranged above one another, and are cast together.

US 2014/0091473 A1 and US 2015/0069623 A1 furthermore describe the 3D semiconductor wafer integration of TMSC, wherein semiconductor wafers are cast in plastic resin and vias are created in the form of through silicon vias or are embedded into the casting compound in the form of metal rods.

WO 1998/037580 A1 deals with the underfilling of CSPs and discloses a holder having a recess with side walls for receiving a semiconductor chip with its carrier as manufacturing intermediate product contained therein.

U.S. Pat. No. 4,953,283 A discloses a holder for machining chips that is made from metal or resin, having a recess for receiving the chips at least partially lined with an elastic means.

Furthermore, US 2015/0303174 A1 relates to complex 3D integration and US 2017/0207204 A1 relates to “integrated fanout packaging”.

Introducing the casting compound may lead to a relative displacement between the semiconductor wafers and also with respect to a predefined intended position for the semiconductor wafer. The hardening-induced shrinkage of the casting compound additionally leads to tensions that may lead to uneven deformation. The dynamic forces of the inflowing casting compound furthermore cause drift of the semiconductor wafers on the substrate. It is also already known that machining the back-side metallization may lead to warpage problems.

To avoid the abovementioned disadvantages, WO 2019/091728 A1, which represents the closest prior art, provides a method in which a substrate made from glass, having at least one recess, formed by corresponding walls, for receiving one or more semiconductor wafers is positioned or fastened in relation to the semiconductor wafers, prior to the introduction of casting compound, such that at least individual semiconductor wafers are surrounded by the walls of the glass substrate, in particular are separated from one another. Thus, by arranging one or more semiconductor wafers in a respective recess and arranging them separately from other semiconductor wafers, these are optimally protected against undesired influences caused by the introduction of the casting compound. It has already been shown in trials that the glass substrate limits the displacement of the semiconductor wafers parallel to the main plane of extent of the substrate or of the plastic substrate carrying the semiconductor wafers to less than 100 μm and, depending on the implementation, to less than 10 μm. To this end, the glass substrate forms a mask having the recesses adapted to the semiconductor wafers, which may preferably already be equipped with through-holes (through glass vias: TGV) and allow a through-connection.

It is furthermore known from this prior art according to WO 2019/091728 A1 to provide, on the walls of the glass substrate, spring elements for maintaining the position and/or orienting the semiconductor wafer in the recess. The introduction of the semiconductor wafer into the corresponding recess may cause a problem here, since the delicate spring elements for this purpose have to be handled suitably between an expanded position, in which they are positioned outside the space taken up by the contour of the semiconductor wafer—referred to here as “contour space”—and a position acting on the semiconductor wafer.

### SUMMARY OF THE INVENTION

To solve this problem, the invention provides a corresponding mounting method for such an integrated semiconductor wafer device, in particular integrated semiconductor component arrangement, as manufacturing intermediate product, which comprises
a glass substrate having at least one recess formed by walls,
one or more semiconductor wafers, in particular semiconductor components, that are to be arranged in the recess, and
at least one spring element engaging in the recess and formed on the glass substrate for maintaining the position and/or orienting the semiconductor wafer or wafers in the recess, comprising the following method steps:
providing the glass substrate with a relaxed spring element engaging in the contour space of the semiconductor wafer to be positioned,
providing a spring manipulator substrate with a manipulation element adapted to the contour space of the semiconductor wafer to be positioned and/or the at least one spring element,
displacing the glass substrate in relation to the spring manipulator substrate such that its manipulation element runs into the recess, pre-tensioning and deflecting the spring element out of the contour space of the semiconductor wafer,
placing the semiconductor wafer into the recess, and
displacing the glass substrate back in relation to the spring manipulator substrate such that its manipulation element moves out of the contour space of the semiconductor wafer, releasing the spring element, as a result of which the at least one spring element acts on the semiconductor wafer to maintain its position and/or orient it in the recess, and a corresponding mounting device for the corresponding performance of the method, comprising a spring manipulator substrate able to be displaced in relation to the glass substrate in the thickness direction thereof, which spring manipulator substrate is provided with at least one manipulation element adapted to the contour space of the semiconductor wafer to be positioned and/or the at least one spring element.

The method according to the invention uses the spring manipulator substrate to achieve a defined, exceedingly gentle manipulation of the spring element or elements on the glass substrate in a technically simple manner.

Since the glass substrate and the spring manipulator substrate are machined by laser radiation through non-linear self-focusing and then subjected to an anisotropic removal of material by etching at an appropriate etching rate and for an appropriate etching duration, virtually flat wall surfaces are generated as boundary surfaces of the recesses and side surfaces of the existing structures in the substrates, meaning that semiconductor wafers are able to be arranged at a very small distance from the side wall surfaces and therefore also from adjacent semiconductor wafers.

In the method for producing the recesses, forming the side wall surfaces, in the glass substrate and spring manipulator substrate, use is made of laser-induced deep etching, which has become known by the name LIDE. In this case, the LIDE method makes it possible to introduce extremely precise holes (through glass via=TGV) and structures at a very high speed, and thus provides the requirements for the rational manufacture of the glass and spring manipulator substrate.

The invention further specifies preferred developments of the mounting method according to the invention. The manipulation element may thus run into its recess to a maximum depth of less than half the thickness of the glass substrate. This represents an expedient compromise between the required manipulation travel for the spring element or elements and the smallest possible trimming of the available depth of the recess to receive the semiconductor wafer.

The manipulation element preferably runs into the recess in the glass substrate from below, meaning that the semiconductor wafer is expediently able to be fitted into the recess from above.

An expedient shape for the manipulation element is a pedestal-shaped projection having a trapezoidal cross section and having lateral manipulation edges for the respective spring element. This projection may be formed, preferably integrally, on a plate-shaped base body of the spring manipulator substrate. The obliquely set lateral manipulation edges result in a gradual and thus gentle action on the delicate spring elements, wherein the manipulation elements themselves are designed to be sufficiently stable for a large number of production cycles.

The semiconductor wafer in the recess is preferably placed on the manipulation element in a raised intermediate position through the relative movement between glass substrate and spring manipulator substrate and lowered into its final position in the recess when the manipulation element is moved out from the recess. Through the extension of the spring manipulator substrate and the associated activation of the spring elements, it is then held and oriented there in the recess by said spring elements.

In one method development, the semiconductor wafer may be subjected to negative pressure as additional fastening for the semiconductor wafer temporarily placed on the manipulation element Similarly, an application of negative pressure between glass substrate and spring manipulator substrate may also ensure a relative displacement between these two components.

In terms of the device, according to one preferred embodiment, suction channels that are continuous in the thickness direction are then formed in the spring manipulator substrate, in particular its base body and/or in the manipulation element.

Exemplary embodiments are illustrated in the drawings and described below in order to further explain the invention.

### BRIEF DESCRIPTION OF THE DRAWINGS

FIG. 1 shows a vertical sectional illustration of a glass substrate having recesses and through glass vias (TGV) in an embodiment not according to the invention,

FIG. 2 shows a horizontal sectional illustration of a glass substrate having recesses and through glass vias in an embodiment likewise not according to the invention,

FIG. 3 shows a vertical sectional illustration of an integrated semiconductor wafer package,

FIG. 4 shows a schematic sectional plan view of one embodiment of an integrated semiconductor wafer device with spring elements for orienting the semiconductor wafer,

FIGS. 5 and 6 show schematic sectional plan views of a glass substrate in a further embodiment having spring elements in two different mounting positions,

FIG. 7 shows a schematic vertical sectional illustration of a mounting device with a glass substrate, with glass substrate and a spring manipulator substrate being in a relative position extended from one another,

FIG. 8 shows an illustration similar to FIG. 7, with spring manipulator substrate retracted into the glass substrate, and

FIGS. 9a-9d show illustrations similar to FIGS. 7 and 8, with successive mounting intermediate steps for the mounting device.

### DESCRIPTION OF THE PREFERRED EMBODIMENTS

FIG. 1 shows the most important features of the glass substrate 1, intended for the mounting method that is described later on. A glass substrate 1 of thickness D is provided with a plurality of recesses 2 and a spacing b. Through-holes 4, which are known as “through glass vias”, TGV for short, are formed in the walls 3, surrounding the recesses 2, of the glass substrate 1, in which through glass vias a metallization 5 is introduced, as is conventional. The glass substrate 1 consists at least substantially of an alkali-free glass, in particular an aluminoborosilicate glass or borosilicate glass.

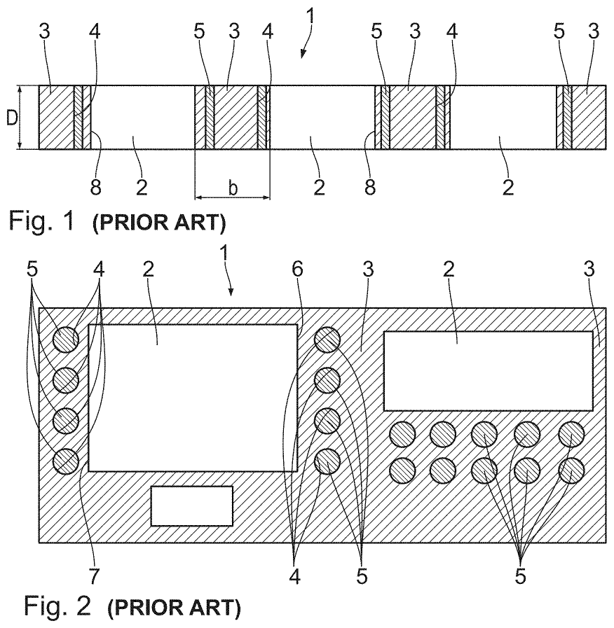

FIG. 2 illustrates the plan view of a similar glass substrate 1 that again has recesses 2 that are rectangular in plan view. In the region of the walls 3, through-holes 4 are introduced on both sides of the recess 2 illustrated on the left in FIG. 2, flanking its narrow sides 6, 7 at a distance. Further through-holes 4 of this type are located in two rows in parallel below the recess 2 illustrated on the right in FIG. 2.

The recesses 2—as illustrated in FIG. 1—may be designed as through-openings, but also as blind holes.

The further geometric ratios in the case of the glass substrates 1 according to FIGS. 1 and 2 are as follows: its material thickness D may be for example <500 μm, preferably <300 μm or even more preferably <100 μm. The wall thickness b of the walls 3 is <500 μm, and preferred gradations are <300 μm, <200 μm, <100 μm or <50 μm, and is preferably less than the material thickness D of the glass substrate 1.

The ratio b/D of the maximum remaining wall thickness b between two recesses 2 in the glass substrate 1 to its material thickness may accordingly be D<1:1, preferably <2:3, <1:3 or <1:6.

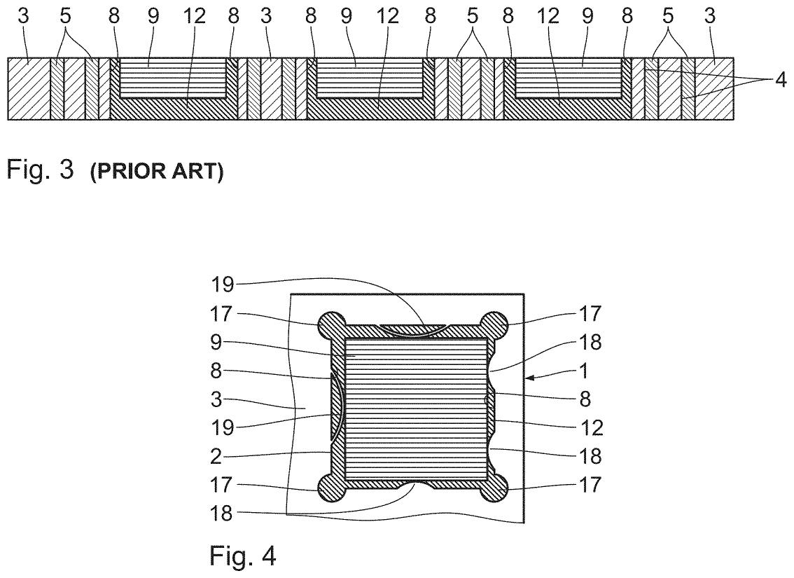

As is apparent from FIG. 3, the size of the recesses 2 in the glass substrate 1 is selected in principle such that semiconductor components 9 are able to be received therein at the smallest possible distance from the side wall surfaces 8. The positions of the recesses 2 are selected such that they correspond to the desired subsequent positioning of the semiconductor components 9, formed as semiconductor wafers, in an integrated semiconductor component arrangement—what is known as a “chip package” or “fanout package”.

FIG. 3 now schematically shows how a glass substrate 1 may be used in the manufacture of a chip package. The distance between the side wall surfaces 8 of the walls 3 and the sides, opposite these, of the semiconductor components 9 is in this case for instance <30 μm, preferably <20 μm, <10 μm or <5 μm.

A casting compound 12 is cast into the recesses 2 in order to fasten the semiconductor components 9 in their position within the glass substrate 1. This results in a compact unit of the glass substrate 1, through-holes 4 introduced therein with a metallization 5 and semiconductor components 9 embedded in the casting compound 12. The further processing of the arrangement according to FIG. 3 by applying a redistribution layer and solder balls positioned thereon for making contact with the semiconductor components 9 is not the subject of the present invention and is described in detail in WO 2019/091728 A1.

In order to counter tilting of the component 9 during the tight fitting of semiconductor components 9 in the respective recesses 2 of the glass substrate 1, it is possible—as illustrated in FIG. 4—to form cutouts 17 for the corners of the components 9 in the glass substrate 1 in the corner regions of the respective recess 2.

Stops 18 projecting from the side wall surface 8 are additionally arranged on the glass substrate 1, thereby avoiding what is known as “overdeterminacy” in the fastening of the position of the semiconductor component 9 in the recess 2.

Finally, the preliminary fastening of the semiconductor component 9 is also additionally further optimized by two spring elements 19 in the side wall surfaces 8, opposite the stops 18, of the glass substrate 1. It should however be pointed out that the construction elements recess 17, stop 18 and spring element 19 may also be inserted separately, in each case on their own or else in various combinations, into different recesses 2 of an integrated semiconductor wafer device.

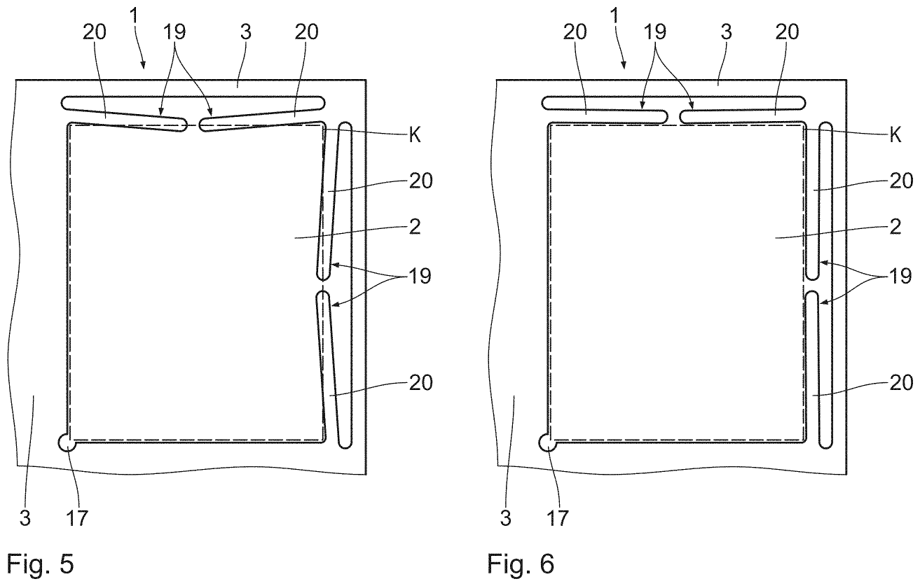

The mounting method implementing the actual invention and the mounting device accordingly used therein is described in more detail below. In this case, FIGS. 5 and 6, similarly to FIG. 4, again show a glass substrate 1 with a recess 2 for receiving a semiconductor wafer, not illustrated here. The latter is indicated only by its contour space K marked in dashed form in FIGS. 5 and 6 and which represents the outer profile taken up by the semiconductor wafer with respect to its plan view. In this embodiment, two spring elements 19 are each formed by spring arms 20 that are connected at one of their ends to the glass substrate and oriented towards one another at their other end, and which project slightly obliquely into the recess 2 in their relaxed position shown in FIG. 5. The spring arms 20 thereby engage in the contour space K. FIG. 6 illustrates the deflected, tensioned position of the spring arms 20 in which these are moved out from the contour space K and no longer intersect same.

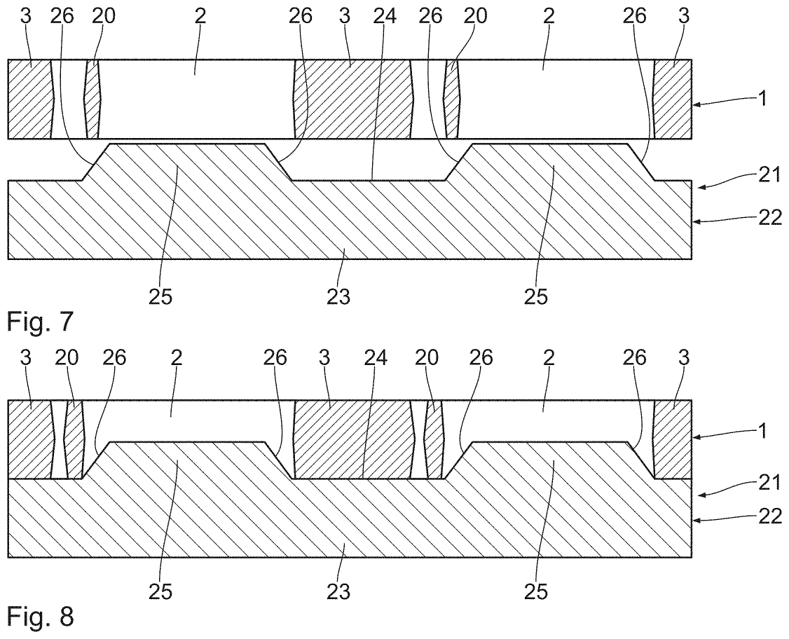

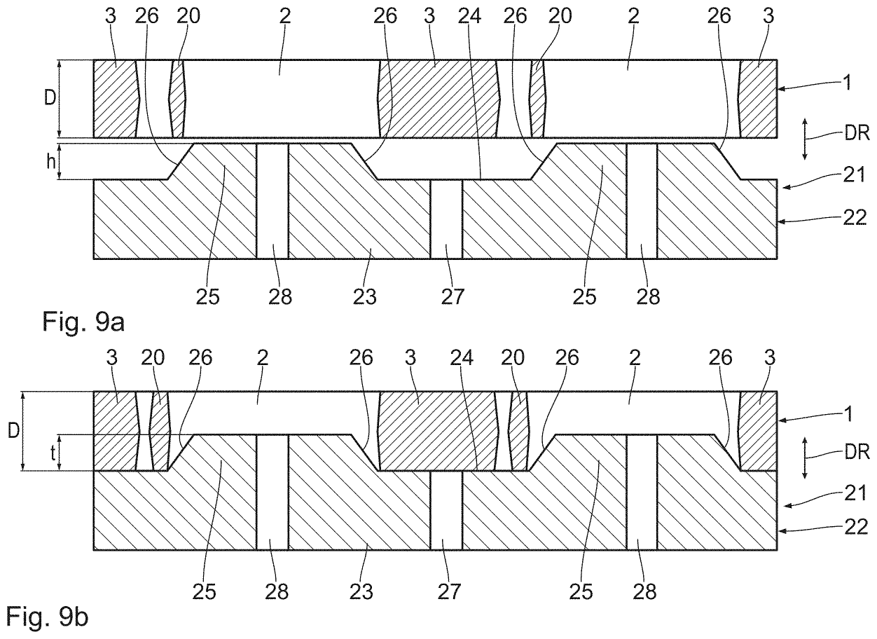

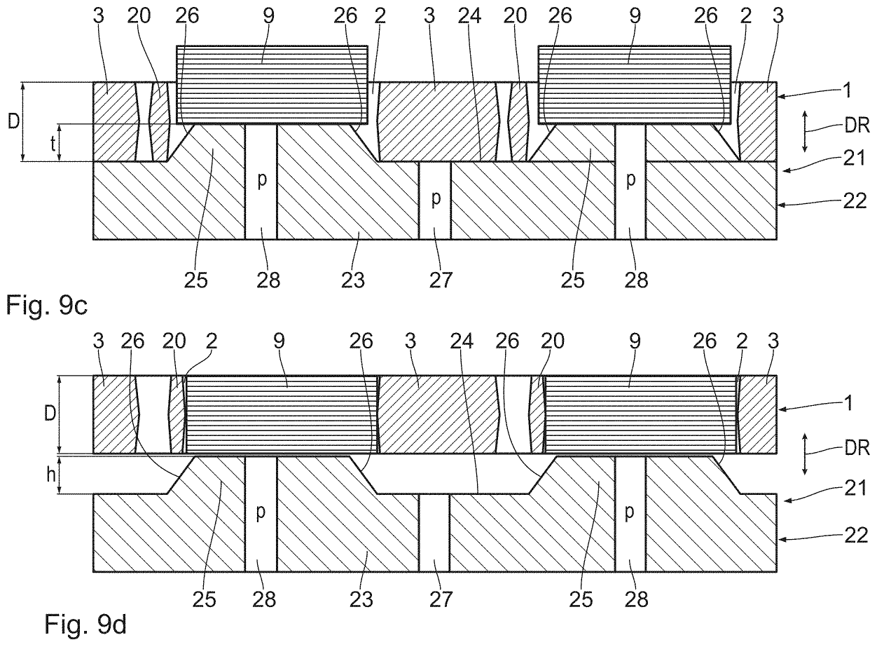

With reference to FIGS. 7 and 8, an explanation is now given of a mounting device 21 according to the invention, whose core component is the spring manipulator substrate 22. This is manufactured similarly to the glass substrate 1 using a corresponding filigree process and has a plate-shaped base body 23 and manipulation elements 25 formed on its upper side 24 in the form of pedestal-shaped projections having a trapezoidal cross section and having lateral manipulation edges 26. The profile and the height of these manipulation elements 25 are selected such that they are able to interact in a suitable manner with the spring arms 20 of the spring elements 19. In detail, in order to displace the glass substrate 1 in relation to the spring manipulator substrate 22, the latter is moved from below counter to the glass substrate 1 such that the manipulation elements 25 run into the recess 2 and, with their manipulation edges 26, gradually grasp the spring arms 20 and bring them out of the relaxed position shown in FIGS. 5 and 7 into the tensioned, outwardly pressed position shown in FIGS. 6 and 8. This step is also shown in FIGS. 9a and 9b.

In this position, the spring arms 20 are pressed outwardly to such an extent that the contour space K is clear and a semiconductor component 9 is thus able to be placed into the recess 2 on the manipulation element 25 located therein from above without any hindrance—see FIG. 9c.

The spring manipulator substrate 22 is then lowered again, as a result of which firstly the respective semiconductor component 9 is lowered back into the recess 2 and secondly the spring aims 20 are released. These thus act on the semiconductor components 9 and orient them positionally accurately in the recess 2. Based on this manufacturing intermediate step, it is then once again possible—as described above and similarly to the prior art—to cast the semiconductor components 9 in the recesses 2 and to apply a redistribution layer and solder balls.

In terms of the device, the spring manipulator substrate 22 still needs to be supplemented by being provided with suction channels 27, 28 that are continuous in the thickness direction DR in the region of the manipulation elements 25 and between them. The suction channels 27 illustrated in the middle in FIGS. 9a-9d are flush with the walls 3 between the recesses 2 and serve to drive the movement during the relative displacement between glass substrate 1 and spring manipulator substrate 22 through the application of negative pressure p. The semiconductor components 9 are likewise fastened in their position on the manipulation elements 25 via the other suction channels 28 through the application of negative pressure p.

The deflection of the spring arms 20 is of an order of magnitude of 5-100 μm. The height h of the manipulation elements 25 and therefore its maximum penetration depth t into the recess is considerably lower, preferably less than half the thickness D of the glass substrate 1.

1-11. (canceled)

12. A mounting method for an integrated semiconductor wafer device as manufacturing intermediate product, which comprises a glass substrate having at least one recess formed by walls, at least one semiconductor wafer that is to be arranged in the recess, and at least one spring element engaging in the recess and formed on the glass substrate for maintaining at least one of the group comprising the position and orienting of the at least one semiconductor wafer in the recess, the method comprising:
providing the glass substrate with a relaxed spring element engaging in the contour space of the semiconductor wafer to be positioned,
providing a spring manipulator substrate with a manipulation element adapted to at least one of the group comprising the contour space of the semiconductor wafer to be positioned and the at least one spring element,
displacing the glass substrate in relation to the spring manipulator substrate such that its manipulation element runs into the recess, pre-tensioning and deflecting the spring element out of the contour space of the semiconductor wafer,
placing the semiconductor wafer into the recess, and
displacing the glass substrate back in relation to the spring manipulator substrate such that its manipulation element moves out of the contour space of the semiconductor wafer, releasing the spring element, as a result of which the at least one spring element acts on the semiconductor wafer to at least one of maintain its position and orient it in the recess.

13. The mounting method according to claim 12, for an integrated semiconductor component arrangement as manufacturing intermediate product.

14. The mounting method according to claim 12, which comprises semiconductor components that are to be arranged in the recess.

15. The mounting method according to claim 12, wherein the manipulation element runs into the recess to a maximum penetration depth of less than half the thickness of the glass substrate.

16. The mounting method according to claim 12, wherein the manipulation element runs into the recess of the glass substrate from below.

17. The mounting method according to claim 12, wherein a projection having a trapezoidal cross section and having a lateral manipulation edge for the spring element is used as manipulation element.

18. The mounting method according to claim 12, wherein the semiconductor wafer in the recess is placed on the manipulation element in a raised intermediate position and lowered into its final position in the recess when the manipulation element is moved out from the recess.

19. The mounting method according to claim 16, wherein the semiconductor wafer placed on the manipulation element is fastened on the manipulation element in the intermediate position through the application of negative pressure.

20. The mounting method according to claim 12, wherein the relative displacement between glass substrate and spring manipulator substrate is achieved through the application of negative pressure between these two components.

21. A mounting device for performing the mounting method, comprising a spring manipulator substrate able to be displaced in relation to the glass substrate in the thickness direction thereof, which spring manipulator substrate is provided with at least one manipulation element adapted to at least one of the group comprising the contour space of the semiconductor wafer to be positioned and the at least one spring element.

22. The mounting device according to claim 21, wherein the spring manipulator substrate is formed from a plate-shaped base body having the at least one manipulation element arranged thereon.

23. The mounting device according to claim 21, wherein the manipulation element is designed as a projection having a trapezoidal cross section and having a lateral manipulation edge for the spring element.

24. The mounting device according to claim 21, wherein suction channels that are continuous in the thickness direction are formed in the spring manipulator substrate.

25. The mounting device according to claim 21, wherein suction channels that are continuous in the thickness direction are formed in at least one of the base body and the manipulation element.
